(19) United States
(12) Patent Application Publication
(10) Pub. No.: US 2014/0248749 A1
(43) Pub. Date: Sep. 4, 2014

(54) STRESS MEMORIZATION TECHNIQUE

(71) Applicant: GLOBALFOUNDRIES INC., Grand Cayman (KY)

(72) Inventors: Jan Hoentschel, Dresden (DE); Stefan Flachowsky, Dresden (DE); Nicolas Sassiat, Dresden (DE); Ralf Richter, Radebeul (DE)

(73) Assignee: GLOBALFOUNDRIES Inc., Grand Cayman (KY)

(21) Appl. No.: 13/783,685

(22) Filed: Mar. 4, 2013

(51) Int. Cl. H01L 21/8238; H01L 29/66

(52) U.S. Cl. CPC H01L 21/823814; H01L 29/66575
USPC 438/231; 438/305

(57) ABSTRACT

A method comprises providing a semiconductor structure comprising a gate structure provided over a semiconductor region. An ion implantation process is performed. In the ion implantation process, a first portion of the semiconductor region adjacent the gate structure and a second portion of the semiconductor region adjacent the gate structure are amorphized so that a first amorphized region and a second amorphized region are formed adjacent the gate structure. An atomic layer deposition process is performed. The atomic layer deposition process deposits a layer of a material having an intrinsic stress over the semiconductor structure. A temperature at which at least a part of the atomic layer deposition process is performed and a duration of the at least a part of the atomic layer deposition process are selected such that the first amorphized region and the second amorphized region are re-crystallized during the atomic layer deposition process.

### BACKGROUND OF THE INVENTION

1. Field of the Invention

Generally, the present disclosure relates to the field of integrated circuits, and, more particularly, to methods of forming integrated circuits wherein a stress memorization technique is employed for providing a stress in a semiconductor material.

2. Description of the Related Art

Integrated circuits include a large number of circuit elements, which include, in particular, field effect transistors. In a field effect transistor, a gate electrode is provided. The gate electrode may be separated from a channel region by a gate insulation layer providing electrical insulation between the gate electrode and the channel region. Adjacent the channel region, a source region and a drain region are provided.

The channel region, the source region and the drain region are formed of semiconductor material, wherein the doping of the channel region is different from the doping of the source region and the drain region. Depending on an electric voltage applied to the gate electrode, the field effect transistor may be switched between an on-state and an off-state, wherein an electric conductivity of the channel region in the on-state is greater than an electric conductivity of the channel region in the off-state.

For improving the current through the channel region of a field effect transistor in the on-state, it has been proposed to provide an elastic stress in the channel region. A tensile stress may increase the mobility of electrons in a semiconductor material such as silicon. Providing a tensile stress in the channel region of an N-channel transistor may help to improve the conductivity of the channel region, so that a greater current through the channel region in the on-state of the transistor may be obtained. A compressive stress in a semiconductor material such as silicon may improve the mobility of holes, so that providing a compressive stress in the channel region of a P-channel transistor may help to obtain a greater current through the channel region of the P-channel transistor in the on-state of the transistor.

In the following, methods for providing stressed channel regions in N-channel transistors and P-channel transistors will be described with reference to FIGS. 1a and 1b.

FIG. 1a shows a schematic cross-sectional view of a semiconductor structure 100 in a first stage of a manufacturing process. The semiconductor structure 100 includes a transistor element 102 formed in a semiconductor region 104 of a substrate 101 and a transistor element 103 formed in a semiconductor region 105 of the substrate 101. A trench isolation structure 106 provides electrical insulation between the transistor element 102 and the transistor element 103, and between the transistor elements 102, 103 and other circuit elements in the semiconductor structure 100 (not shown).

In the manufacturing process, an N-channel transistor may be formed from transistor element 102, and a P-channel transistor may be formed from transistor element 103. The semiconductor regions 104, 105 may be doped in accordance with a doping of the channel regions of the transistor elements 102, 103, whose doping depends on the type of transistor to be formed. Hence, the semiconductor region 104 may be P-doped, and the semiconductor region 105 may be N-doped.

The substrate wherein the semiconductor regions 104, 105 are provided may include a semiconductor material such as silicon. In the transistor element 103, a layer 133 of a stress-creating material, such as silicon/germanium, may be provided. Due to the lattice mismatch between the materials of the layer 133 of stress-creating material and the substrate, a compressive stress may be provided in the semiconductor region 105.

The transistor element 102 includes a gate structure 107. The gate structure 107 includes a gate electrode 111. The gate electrode 111 may include a metal portion 110. Other parts of the gate electrode 111 may be formed from polysilicon. A gate insulation layer 109 separates the gate electrode 111 from the semiconductor region 104. On a top surface of the gate electrode 111, a cap layer 112 may be provided. Adjacent the gate electrode 111, a silicon dioxide sidewall spacer 118, which may be separated from the gate electrode 111 by a liner layer 117 including silicon nitride, may be provided.

Similarly, the transistor element 103 includes a gate structure 108 including a gate electrode 115 with a metal portion 114, a gate insulation layer 113, a silicon dioxide sidewall spacer 120 and a liner layer 119. Furthermore, a cap layer 116 may be formed on a top surface of the gate electrode 115.

Adjacent the gate structure 107 of the transistor element 102, a source extension 123 and a drain extension 124 may be provided. The source extension 123 and the drain extension 124 may be N-doped. Additionally, halo regions 127, 128, which may be P-doped, may be provided. The transistor element 103 may include a source extension 125 and a drain extension 126, which may be P-doped, and halo regions 129, 130, which may be N-doped.

As described above, the layer 133 of stress-creating material may provide a compressive stress in the channel region of the P-channel transistor element 103. In the channel region of the N-channel transistor element 102, a tensile stress may be provided. For this purpose, a stress memorization technique may be employed, which will be described in the following.

An amorphized region 131 may be formed on a source side of the gate structure 107, and an amorphized region 132 may be formed on a drain side of the gate structure 107. For forming the amorphized regions 131, 132, an ion implantation process, wherein ions of a non-doping element, such as xenon or germanium, are implanted into the semiconductor structure 100, may be performed.

The irradiation of semiconductor material in the semiconductor region 104 with ions may displace atoms from their positions in the crystal lattice, so that the crystalline order of the semiconductor material is destroyed. Portions of the semiconductor region 104 below the gate structure 107 may be protected from the irradiation with ions by gate structure 107, so that the amorphized regions 131, 132 are separated from each other by a substantially crystalline region below the gate structure 107. A depth of the amorphized regions 131, 132 may be controlled by an appropriate selection of the energy of the ions used in the ion implantation process.

After the formation of the amorphized regions 131, 132, a liner layer 121 including silicon dioxide and a stressed silicon nitride layer 122 may be formed over the semiconductor structure 100. The liner layer 121 and the stressed silicon nitride layer 122 may be formed by means of chemical vapor deposition and/or plasma enhanced chemical vapor deposition. Parameters of the deposition process employed for forming the stressed silicon nitride layer 122 may be adapted such that a tensile stress is obtained in the stressed silicon nitride layer 122.

The tensile stress provided by the stressed silicon nitride layer 122 may create a tensile stress in portions of the semiconductor material of the substrate 101. In particular, a tensile stress may be created in the amorphized regions 131, 132.

FIG. 1b shows a schematic cross-sectional view of the semiconductor structure 100 in a later stage of the manufacturing process. After the formation of the stressed silicon nitride layer 122, an annealing process is performed for re-crystallizing the amorphized regions 131, 132. The annealing process is performed after the completion of the formation of the stressed silicon nitride layer 122.

Since the re-crystallization of the amorphized regions 131, 132 occurs in the presence of the tensile stress provided by the stressed silicon nitride layer 122, the tensile stress may influence the structure of the crystal lattice obtained in the re-crystallization process. Thus, stressed regions 138, 139 may be provided on the source side and the drain side of the gate structure 107 of the transistor element 102. The stress of the stressed regions 138, 139 may provide a tensile stress in the channel region of the transistor element 102.

Thereafter, an anisotropic etch process may be performed for forming a sidewall spacer 140 adjacent the gate structure 107 and a sidewall spacer 141 adjacent the gate structure 108 from portions of the stressed silicon nitride layer 122. Then, ion implantation processes may be performed for forming an N-doped source region 134 and an N-doped drain region 135 in the transistor element 102 and P-doped source and drain regions 136, 137 in the transistor element 108.

Thereafter, portions of the liner layer 121 which are not covered by the sidewall spacers 140, 141 and the cap layers 112, 116 of the gate structures 107, 108 may be removed, and silicide portions 142, 143, 144, 145, 146, 147 may be formed in the source regions, drain regions and gate electrodes of the transistor elements 102, 103.

The stressed regions 138, 139 may maintain their intrinsic stress even after the removal of portions of the stressed silicon nitride layer 122 other than those portions from which the sidewall spacers 140, 141 are formed, so that a tensile stress in the channel region of the transistor formed from transistor element 102 is maintained. This effect is denoted as “stress memorization.” The stress in the channel region of the transistor formed from the transistor element 103 may be substantially as provided by the stress-creating layer 133, so that a compressive stress is obtained in the channel region of the transistor formed from transistor element 103.

A problem of the above-described stress memorization technique is that chemical vapor deposition and plasma enhanced chemical vapor deposition techniques employed for the formation of the stressed silicon nitride layer may be subject to loading effects, wherein the thickness of the stressed silicon nitride layer 122 depends on a pitch between adjacent transistor elements. This can cause a shift of the threshold voltage between differently pitched transistors, such as single pitch and dual pitch transistor devices. This can adversely affect the performance of an integrated circuit formed in the semiconductor structure 100, and can reduce the yield of the production process.

A further problem of the above-described stress memorization technique is that the annealing process that is performed for re-crystallizing the amorphized regions 131, 132 is performed as a separate step of the manufacturing process, which may increase the complexity of the manufacturing process.

The present disclosure provides manufacturing processes wherein at least a part of the above-mentioned problems may be avoided or at least reduced.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method disclosed herein includes providing a semiconductor structure. The semiconductor structure includes a gate structure provided over a semiconductor region. An ion implantation process is performed. The ion implantation process amorphizes a first portion of the semiconductor region adjacent the gate structure and a second portion of the semiconductor region adjacent the gate structure, so that a first amorphized region and a second amorphized region are formed adjacent the gate structure. An atomic layer deposition process is performed. The atomic layer deposition process deposits a layer of a material having an intrinsic stress over the semiconductor structure. A temperature at which at least a part of the atomic layer deposition process is performed and a duration of the at least a part of the atomic layer deposition process are selected such that the first amorphized region and the second amorphized region re-crystallize during the atomic layer deposition process.

Another illustrative method disclosed herein includes providing a semiconductor structure. The semiconductor structure includes a first transistor element and a second transistor element. The first transistor element includes a first gate structure provided on a first semiconductor region. The second transistor element includes a second gate structure provided on a second semiconductor region. The method further includes forming a first amorphized region in the first semiconductor region adjacent the first gate structure and a second amorphized region in the first semiconductor region adjacent the first gate structure. In the second semiconductor region, no amorphized region is formed. An atomic layer deposition process is performed. The atomic layer deposition process deposits a layer of a material having an intrinsic stress above the first semiconductor region and the second semiconductor region. A temperature at which at least a part of the atomic layer deposition process is performed and a duration of the at least a part of the atomic layer deposition process are selected such that the first amorphized region and the second amorphized region re-crystallize substantially completely during the atomic layer deposition process.

### BRIEF DESCRIPTION OF THE DRAWINGS

The disclosure may be understood by reference to the following description taken in conjunction with the accompanying drawings, in which like reference numerals identify like elements, and in which:

FIGS. 1a and 1b show schematic cross-sectional views of a semiconductor structure in stages of a conventional manufacturing process; and

FIGS. 2a-2c show schematic cross-sectional views of a semiconductor structure in stages of a method according to the present disclosure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Continuous scaling of transistors in integrated circuits towards the 20 nm technology node and/or the 14 nm technology node may increase marginalities, variabilities and challenges in manufacturability. Continuing scaling in poly pitches between transistor devices may result in a minimum space where several implants, stress memorization techniques, formation of silicides, dual stress liners and strained contacts have to find their space. Thus, a further scaling of sizes may require a substantial effort to figure out ways to solve all the marginalities in each individual process step and to reduce variability and marginalities to build a very robust process.

Aspects of the present disclosure relate to a reduction of variability between isolated and densely nested transistor devices by using a very conformal spacer material. In the 28 nm technology node and below, it can be of advantage to use a very conformal silicon nitride spacer in the formation of source and drain regions of transistor devices for reducing a variability of features of spacers between single pitch and dual pitch transistor devices.

Conventional chemical vapor deposition processes and/or plasma enhanced chemical vapor deposition processes for the deposition of silicon nitride may cause a loading effect for different pitch devices. This may cause a shift of a threshold voltage of transistor devices, and different targeting and performance for similar transistor devices. Moreover, it may lead to a degradation of product performance and may reduce the yield of the manufacturing process.

Using a conformal silicon nitride sidewall spacer wherein atomic layer deposition is employed for depositing silicon nitride may help to reduce variations between isolated and nested transistor devices, which may help to improve the targeting as well as the performance of different pitch transistor devices.

Conformal atomic layer deposition of silicon nitride may be done at relatively low temperatures, wherein a relatively long deposition time may be required, or at increased temperatures, wherein, in some embodiments, a faster deposition may be obtained.

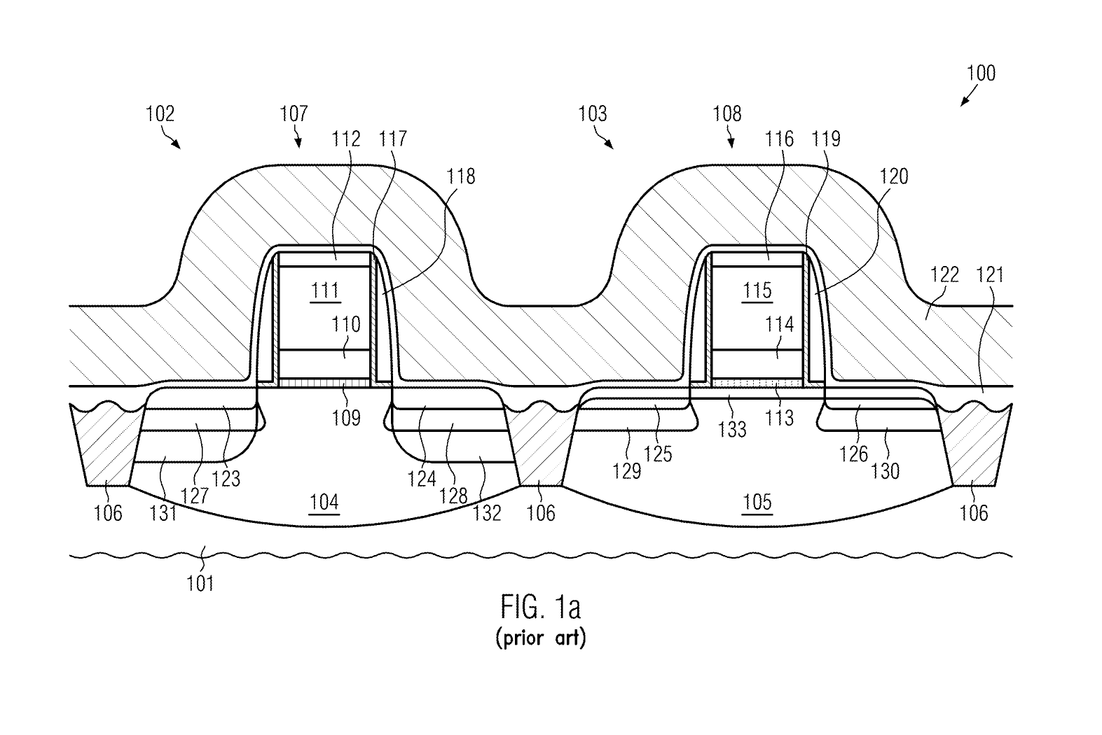

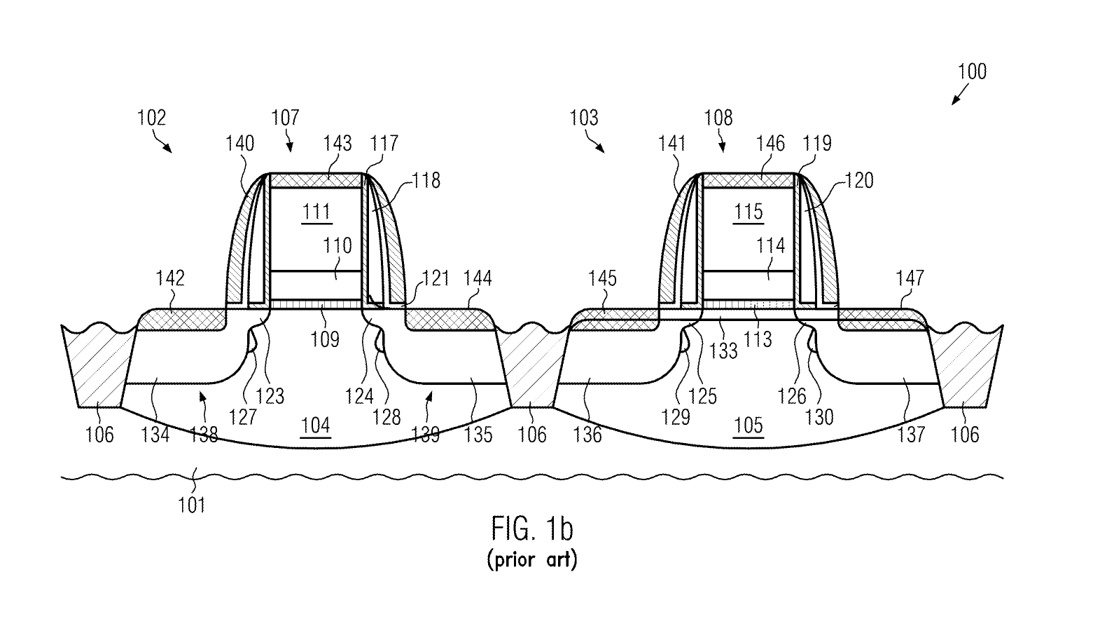

When the entire atomic layer deposition of silicon nitride is performed at a relatively low temperature of about 400° C., a separate thermal anneal as described above with reference to FIGS. 1a and 1b may be required to implement a stress memorization effect that may improve the performance of transistor devices.

Aspects of the present disclosure provide atomic layer deposition processes that may be performed under different temperature conditions. By performing an atomic layer deposition of silicon nitride at an increased temperature, a re-crystallization of amorphized regions in a semiconductor structure during the deposition process may be obtained.

A silicon nitride layer deposited by atomic layer deposition may have an even greater intrinsic stress than silicon nitride layers formed by means of chemical vapor deposition or plasma enhanced chemical vapor deposition. Due to the stress provided by the silicon nitride layer and due to the re-crystallization of amorphized regions during the atomic layer deposition process, a formation of intrinsically stressed regions in a semiconductor material may be obtained already during the deposition of a silicon nitride layer by means of atomic layer deposition. Thus, a separate annealing process for re-crystallizing amorphized regions is not needed and may be saved, while stress memorization effects may still occur and improve the performance of transistor devices.

Moreover, using an atomic layer deposition process for depositing silicon nitride may help to reduce variations between isolated and nested transistor devices, since atomic layer deposition may allow the formation of very conformal silicon nitride layers.

After the completion of the atomic layer deposition process, the silicon nitride layer may be employed for forming sidewall spacers, which may then be used for providing a desired distance between gate electrodes and source and drain regions formed by means of ion implantation.

Atomic layer deposition of silicon nitride may be performed at relatively low deposition temperatures of about 400° C., wherein a relatively long duration of the deposition process of up to about seven hours may be required for obtaining a desired thickness of the silicon nitride layer. Performing an atomic layer deposition process at relatively low temperature may help to reduce an influence of the width of a transistor device on the threshold voltage, which has been attributed to a thermally activated diffusion of oxygen from trench isolation structures filled with silicon dioxide into the channel region of the transistor. In addition to requiring a long duration of the deposition process, an additional thermal anneal similar to that described above with reference to FIGS. 1a and 1b may be required for performing a stress memorization technique if the entire atomic layer deposition process is performed at low temperature, since, at a temperature of 400° C., substantially no re-crystallization of amorphous silicon occurs.

The present disclosure provides methods wherein the conformal material layer, for example a silicon nitride layer, which may be employed in a stress memorization technique, and from which sidewall spacers may also be formed, is deposited at a higher temperature, which may be in a range from about 500-600° C.

At the higher temperature, a re-crystallization of amorphized regions may occur, and since the conformal silicon nitride layer deposited by the atomic layer deposition process may have a relatively high intrinsic strain, an in situ stress memorization effect may occur. An additional thermal anneal as described above with reference to FIGS. 1a and 1b may be omitted. Hence, the manufacturing time and the costs of the manufacturing process may be reduced. Moreover, in some embodiments, the duration of the atomic layer deposition process may also be reduced.

In some embodiments, in the formation of amorphized regions in a semiconductor material, ions of fluorine and/or nitrogen may be implanted into the semiconductor material, in addition to ions of non-doping elements, such as ions of noble gases or ions of elements from the carbon group of the periodic table of elements such as carbon, silicon and/or germanium. This may help to avoid a diffusion of oxygen from trench isolation structures into the semiconductor material, and may help to reduce a variation of the threshold voltage of transistor devices with the width of the channel region of the transistor devices.

Further advantages that may be obtained in some embodiments may include an increased manufacturability and lower cost, an increase in device and product performance, lower overall leakage in complex design structures due to an overall better device targeting, and an increase in product yield. In embodiments, a same targeting may be employed for isolated and densely nested transistor devices, and a solid encapsulation of high-k metal gate structures may be provided.

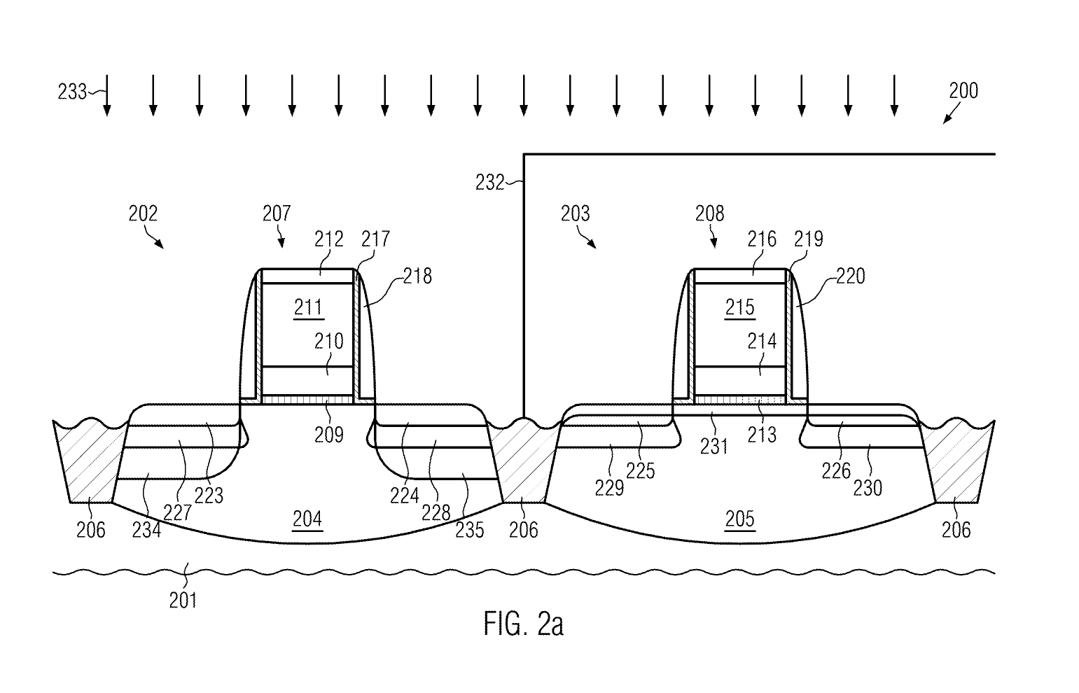

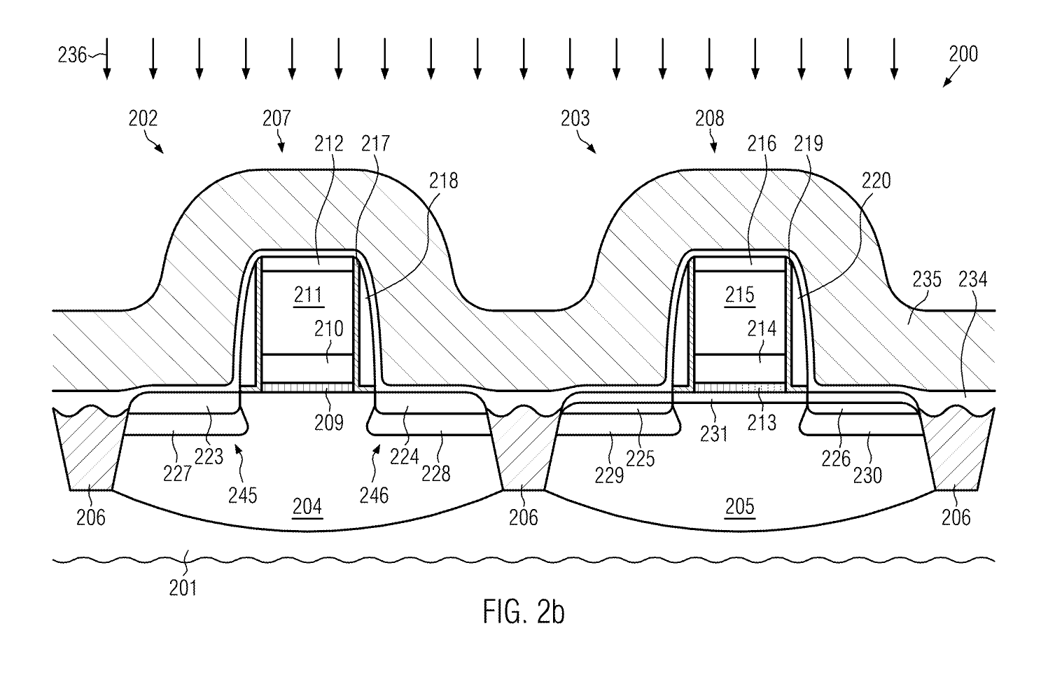

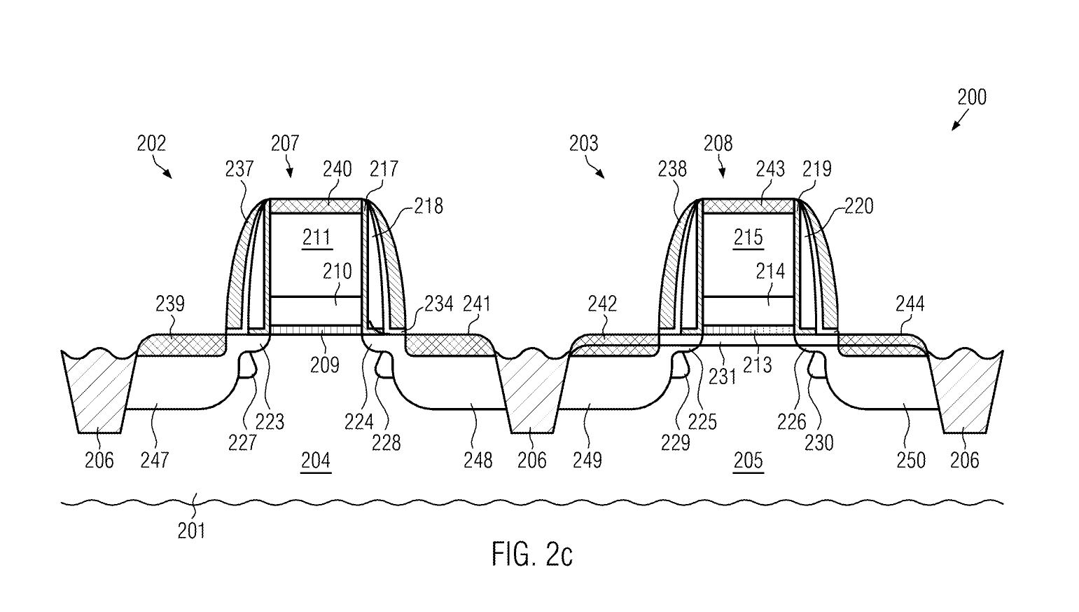

Further embodiments will be described with reference to FIGS. 2a-2c. FIG. 2a shows a schematic cross-sectional view of a semiconductor structure 200 in a stage of a method according to the present disclosure. The semiconductor structure 200 includes a substrate 201. The substrate 201 may include silicon.

In some embodiments, the substrate 201 may be a bulk semiconductor substrate, for example, a silicon wafer or a silicon die. In other embodiments, the substrate 201 may be a semiconductor-on-insulator (SOI) substrate wherein a relatively thin layer of a semiconductor material, such as silicon, is formed above a layer of an electrically insulating material, such as silicon dioxide. The layer of electrically insulating material may provide electrical insulation between the layer of semiconductor material and other portions of the SOI substrate, such as a silicon wafer on which the layer of semiconductor material and the layer of electrically insulating material are provided.

The semiconductor structure 200 includes a transistor element 202 and a transistor element 203. In the method described in the following, an N-channel transistor may be formed from the transistor element 202, and a P-channel transistor may be formed from the transistor element 203.

The transistor element 202 includes a gate structure 207 provided over a semiconductor region 204. The semiconductor region 204 may be doped with a P-type dopant, in accordance with the doping of the channel region of the N-channel transistor to be formed from transistor element 202.

Similarly, the transistor element 203 includes a gate structure 208 formed above a semiconductor region 205. The semiconductor region 205 may be doped with an N-type dopant, in accordance with the doping of the channel region of the P-type transistor to be formed from transistor element 203.

A trench isolation structure 206 may electrically insulate the semiconductor regions 204, 205 from each other. Moreover, the trench isolation structure 206 may provide electrical insulation between the semiconductor regions 204, 205 and other circuit elements in the semiconductor structure 200. The trench isolation structure 206 may be a shallow trench isolation structure wherein silicon dioxide is provided as a dielectric material providing electrical insulation.

The semiconductor regions 204, 205 may be doped by means of ion implantation processes, wherein ions of a dopant material are implanted into the semiconductor structure 200. For doping the semiconductor region 204, the semiconductor structure 200 may be irradiated with ions of a P-type dopant, wherein the semiconductor region 205 may be covered by a mask so that substantially no P-type dopant is implanted into the semiconductor region 205.

For doping the semiconductor region 205, the semiconductor structure 200 may be irradiated with ions of an N-type dopant, wherein the semiconductor region 204 may be covered by a mask to substantially avoid an implantation of N-type dopant into the semiconductor region 204.

The trench isolation structure 206 may be formed by means of techniques of photolithography, etching, oxidation and deposition.

The semiconductor region 205 may include a stress-creating layer 231 that includes a different semiconductor material than the rest of the semiconductor region 205. In some embodiments, the stress-creating layer 231 may include silicon/germanium, and the rest of the semiconductor region 205 may include silicon. Silicon/germanium has a greater lattice constant than silicon. Thus, there is a lattice mismatch between the material of the stress-creating layer 231 and the material of the rest of the semiconductor region 205. The lattice mismatch may create a compressive stress, in particular in a vicinity of the interface between the stress-creating layer 231 and the rest of the semiconductor region 205. The compressive stress may increase the mobility of holes in the channel region of the P-type transistor to be formed from the transistor element 203.

The stress-creating layer 231 may be formed by means of a selective epitaxial growth process for growing silicon/germanium on silicon. During the selective epitaxial growth process, the semiconductor region 204 may be covered by a mask, for example, a hard mask including silicon dioxide or silicon nitride. Due to the selectivity of the epitaxial growth process, substantially no deposition of germanium or only a deposition of a small amount of silicon/germanium is obtained on the mask. After the formation of the stress-creating layer 231, the mask may be removed.

The gate structure 207 of the transistor element 202 may include a gate electrode 211 and a gate insulation layer 209 that is provided between the gate electrode 211 and the semiconductor region 204. The gate insulation layer 209 provides electrical insulation between the gate electrode 211 and the semiconductor region 204. The gate electrode 211 may include a metal portion 210 in a lower portion of the gate electrode 211 adjacent the gate insulation layer 209, whereas the rest of the gate electrode 211 may include polysilicon. On a top surface of the gate electrode 211, a cap layer 212, which may include silicon dioxide, may be provided. At sidewalls of the gate electrode 211, a sidewall spacer 218, that may include silicon dioxide and may be separated from the gate electrode 211 by a liner layer 217, may be provided. The liner layer 217 may include silicon nitride.

Similarly, the gate structure 208 of the transistor element 203 may include a gate insulation layer 213, a gate electrode 215 that may include a metal portion 214, a cap layer 216, a sidewall spacer 220 and a liner layer 219.

The gate structures 207, 208 may be formed after the doping of the semiconductor regions 204, 205 and after the formation of the trench isolation structure 206 and the stress-creating layer 231. For forming the gate structures 207, 208, a layer including a material of the gate insulation layers 209, 213, for example, a layer of a high-k material such as hafnium silicon oxynitride, may be formed, for example, by means of a chemical vapor deposition process or a plasma enhanced chemical vapor deposition process.

Thereafter, a layer including a material of the metal portion 210 of the gate structure 207 may be formed over the semiconductor region 204, and a layer including a material of the metal portion 214 of the gate electrode 215 may be formed over the semiconductor region 205.

In some embodiments, the metal portions 210, 214 may include the same material, for example titanium nitride. In such embodiments, a contiguous layer of the material of the metal portions 210, 214 may be deposited over the semiconductor structure 200, for example by means of a chemical vapor deposition process or a plasma-enhanced chemical vapor deposition process.

In other embodiments, the metal portions 210, 214 may include different materials. For example, the metal portion 210 of the gate electrode 211 of N-channel transistor element 202 may include lanthanum (La) or lanthanum nitride (LaN), and the metal portion 214 of the gate electrode 215 of P-channel transistor element 203 may include aluminum (Al) or aluminum nitride (AlN). In such embodiments, techniques of photolithography, etching and deposition may be employed for forming a layer of the material of metal portion 210 over the semiconductor region 204 but not over the semiconductor region 205 and for forming a layer of the material of metal portion 214 over the semiconductor region 205 but not over the semiconductor region 204.

Additionally, a layer of the material from which the rest of the gate electrodes 211, 215 are formed, for example, a polysilicon layer, and a layer of the material from which the cap layers 212, 216 are formed, for example, a silicon dioxide layer, may be deposited over the semiconductor structure 200. Thereafter, the layer including the material of the gate insulation layers 209, 213, the one or more layers including the one or more materials of the metal portions 210, 214, the layer including the material of the rest of the gate electrodes 211, 215 and the layer including the material of the cap layers 212, 216 may be patterned by means of a photolithography process to form the gate electrodes 211, 215 covered by cap layers 212, 216.

Thereafter, a layer of the material of liner layers 217, 219, for example a layer of silicon nitride, and a layer of the material of sidewall spacers 218, 220, for example a layer of silicon dioxide, may be deposited over the semiconductor structure 200 and one or more etch processes, which may include an anisotropic etch process adapted for removing the material of the sidewall spacers 218, 220 from portions of the semiconductor structure 200 having a substantially horizontal surface, may be performed for forming the sidewall spacers 218, 220 adjacent the gate electrodes 211, 215.

After the formation of the gate structures 207, 208, a source extension 223 and a drain extension 224 may be formed in the semiconductor region 204. Similarly, a source extension 225 and a drain extension 226 may be formed in the semiconductor region 205. The source and drain extensions 223, 224 in the N-channel transistor element 202 may include an N-type dopant, and the source and drain extensions 225, 226 in the P-channel transistor element 203 may include a P-type dopant. Additionally, halo regions 227, 228 including a P-type dopant may be formed in the N-channel transistor element 202, and halo regions 229, 230 including an N-type dopant may be formed in the P-channel transistor element 203. The source and drain regions 223, 224, 225, 226 and the halo regions 227, 228, 229, 230 may be formed by means of known ion implantation processes.

After the formation of the gate structures 207, 208, amorphized regions 234, 235 may be formed adjacent the gate structure 207 of the transistor element 202. The amorphized region 234 may be provided at a source side of the gate structure 207, where the source extension 223 is located, and the amorphized region 235 may be provided at a drain side of the gate structure 207, where the drain extension 224 is located.

In the formation of the amorphized regions 234, 235, the crystal lattice structure of the semiconductor material of the semiconductor region 204 may be destroyed in the amorphized regions 234, 235, so that the amorphized regions 234, 235 include amorphous semiconductor material, for example amorphous silicon. An extension along a thickness direction of the substrate 201 (vertical in the plane of drawing of FIG. 2a), which can also be denoted as depth of the amorphized regions 234, 235, may be greater than a depth of the source and drain extensions 223, 224 and a depth of the halo regions 227, 228, so that at least portions of the source extension 223, the drain extension 224 and the halo regions 227, 228 are located within the amorphized regions 234, 235.

In the transistor element 203, no amorphized regions are formed.

For forming amorphized regions 234, 235 in the transistor element 202 but not in the transistor element 203, a mask 232 may be formed. The mask 232 may include a photoresist, and may be formed by means of a photolithography process. The mask 232 covers the transistor element 203, and does not cover the transistor element 202.

After the formation of the mask 232, an ion implantation process may be performed, as schematically denoted by arrows 233 in FIG. 2a.

In the ion implantation process 233, the semiconductor structure 200 is irradiated with energetic ions of a non-doping substance that substantially does not alter the charge carrier concentration in the semiconductor material of the semiconductor region 204 or has only a relatively small influence on the charge carrier concentration when it is included into the semiconductor material.

In some embodiments, the ion implantation process 233 may include an irradiation of the semiconductor structure 200 with ions of a non-doping element, for example ions of a noble gas, for example ions of helium, neon, argon, krypton and/or xenon. Alternatively or additionally, the ion implantation process 233 may include an irradiation of the semiconductor structure 200 with ions of an element from the carbon group of the periodic table of elements, in particular an irradiation with ions of carbon, silicon and/or germanium.

An energy of the ions used in the ion implantation process 233 may be in a range from about 25-80 keV, and an ion dose may be in a range from about 5·10¹⁴ ions/cm² to about 10¹⁷ ions/cm².

In addition to ions of a noble gas or ions of an element from the carbon group of the periodic table of elements, in the ion implantation process 233, a co-implantation process may be performed, wherein the semiconductor structure 200 is irradiated with ions of fluorine and/or nitrogen. A dose of the ions of fluorine and/or nitrogen may be in a range from about 10¹⁴ ions/cm² to about 10¹⁷ ions/cm², and an energy of the ions of fluorine and/or nitrogen may be in the same range as the energy of the ions of the non-doping element.

Performing a co-implantation of ions of fluorine and/or nitrogen during the ion implantation process 233 may help to reduce variations in the threshold voltages of transistors formed in the semiconductor structure 200 that have a different width of their channel regions (an extension of the channel region of the transistor element in a direction perpendicular to the length direction from the source region to the drain region), which may, in particular, be an issue for N-channel transistors such as the transistor formed from transistor element 202.

Variations of the threshold voltage of transistor devices having different widths of their channel regions have been attributed to an accumulation of oxygen in portions of the transistor devices. The accumulation of oxygen may be caused by thermal diffusion of oxygen from trench isolation structure 206 into the semiconductor material of the semiconductor regions 204, 205. The amount of oxygen included into the semiconductor region of a particular transistor may depend on the width of the channel region of the transistor, so that the threshold voltage of transistors may depend on the width of the channel region.

The presence of fluorine and/or nitrogen may help to reduce the influence of the presence of oxygen on the threshold voltage. Hence, providing a co-implantation of fluorine and/or nitrogen during the ion implantation process 233 may help to avoid adverse influences of exposing the semiconductor structure 200 to relatively high temperatures in later stages of the manufacturing process, for example during the atomic layer epitaxy process that will be described below with reference to FIG. 2b.

FIG. 2b shows a schematic cross-sectional view of the semiconductor structure 200 in a later stage of the manufacturing process. After the formation of the amorphized regions 234, 235, the mask 232 may be removed. Thereafter, a liner layer 234 may be formed. The liner layer 234 may include silicon dioxide, and may be formed by means of a chemical vapor deposition process or a plasma enhanced chemical vapor deposition process.

After the formation of the liner layer 234, an atomic layer deposition process, schematically denoted by arrows 236 in FIG. 2b, may be performed. In the atomic layer deposition process 236, a layer 235 of a material having an intrinsic stress is deposited over the semiconductor structure. The layer 235 may include silicon nitride, and the silicon nitride may have an intrinsic tensile stress of about 1 GPa.

In the atomic layer deposition process 236, a first precursor and a second precursor are alternately supplied to a surface of the semiconductor structure 200. In embodiments wherein the layer 235 includes silicon nitride, the first precursor may include silicon but no nitrogen, and the second precursor may include nitrogen but no silicon. For example, the first precursor may include monochlorosilane (SiClH₃), dichlorosilane (SiCl₂H₂), trichlorosilane (SiCl₃H) and/or tetrachlorosilane (SiCl₄). The second precursor may include ammonia (NH₃) and/or hydrazine (N₂H₄).

The atomic layer deposition process 236 includes a plurality of atomic layer deposition cycles. Each cycle includes a first phase and a second phase. During the first phase, the first precursor is supplied to the surface of the semiconductor structure 200, but no second precursor is supplied. In the second phase, the second precursor is supplied to the surface of the semiconductor structure 200, but no first precursor is supplied.

Parameters of the atomic layer deposition process, such as a temperature at which the atomic layer deposition process is performed, durations of the cycles and the phases of the cycles, as well as pressures of the first and the second precursor during the first and the second phase of each atomic layer deposition cycle, may be adapted such that, during the first phase of each atomic layer deposition cycle, a monolayer of the first precursor is formed on the surface of the semiconductor structure 200. The binding of molecules of the first precursor to a monolayer of the first precursor already formed on the surface of the semiconductor structure 200 may be weaker than the binding of the molecules of the first precursor to an uncovered surface of the semiconductor structure 200. Therefore, after the formation of the monolayer of the first precursor, substantially no further deposition of the first precursor on the surface of the semiconductor structure 200 occurs.

In the second phase of each atomic layer deposition cycle, the second precursor reacts with the first precursor absorbed on the surface of the semiconductor structure 200, and the material of the layer 235 is formed in the reaction. The parameters of the atomic layer deposition process may be adapted such that no second precursor other than the amount of second precursor consumed in the reaction with the first precursor is deposited on the surfaces of the semiconductor structure 200.

Therefore, the amount of the material of the layer 235 that is formed in each atomic layer deposition cycle is substantially limited by the amount of the first precursor that is deposited on the surface of the semiconductor structure 200 during the first phase. Hence, the atomic layer deposition process proceeds in a self-limiting manner, wherein, in each atomic layer deposition cycle, a particular amount of the material of the layer 235 is deposited.

The thickness of the layer 235 may be controlled by an appropriate selection of the number of atomic layer deposition cycles that is performed during the atomic layer deposition process 236. In some embodiments, the layer 235 may have a thickness of about 22 nm.

Due to the self-limiting growth mechanism of the atomic layer deposition process 236, a relatively good conformity of the deposition process may be obtained. In a conformal deposition process, a thickness of the deposited material layer (measured in a direction perpendicular to the surface portion on which the material layer is deposited) is substantially independent of an orientation of the surface portion. Thus, the thickness of the layer 235 of material formed in the atomic layer deposition process 236 may be substantially equal on substantially horizontal portions of the surface of the semiconductor structure 200, such as, for example, the top surfaces of the gate structures 207, 208 and the surfaces of the semiconductor regions 204, 205 adjacent the gate structures 207, 208, and on inclined portions of the surface of the semiconductor structure 200, such as sidewalls of the gate structures 207, 208. Moreover, the thickness of the layer 235 of material may be substantially independent of a pitch between adjacent transistor devices.

Atomic layer deposition may be performed in a relatively large range of temperatures. In particular, atomic layer deposition of silicon nitride may be performed at temperatures in a range from about 400-700° C. The pressure of the first precursor during the first phase of each cycle of the atomic layer deposition process and the pressure of the second precursor during the second phase of each cycle of the atomic layer deposition process, and the duration of the atomic layer deposition cycles, as well as the durations of the first and the second phases of the atomic layer deposition cycles at each respective temperature, may be adapted such that a self-limiting growth of the material of the layer 235 is obtained within the range of temperatures.

In embodiments wherein the atomic layer process is performed at a temperature in a range from about 500-550° C., the atomic layer deposition process may be performed in an atmosphere having a pressure in a range from about 50-80 Torr, which may comprise an inert gas such as molecular nitrogen (N₂) in addition to a respective one of ammonia (NH₃) and dichlorosilane (SiCl₂H₂), which may be employed as precursors, as described above. The duration of the atomic layer deposition process may be in a range from about one hour to about seven hours, in particular in a range from about two hours to about seven hours.

In other embodiments, for example in embodiments wherein the atomic layer deposition process is performed at a different temperature, different parameters of the atomic layer deposition process may be employed, which may be optimized by means of routine experiments wherein, optionally, the above-mentioned parameters may be used as starting values.

A temperature at which at least a part of the atomic layer deposition process 236 is performed, and a duration of the at least a part of the atomic layer deposition process 236 may be selected such that the amorphized regions 234, 235 re-crystallize during the atomic layer deposition process 236. In particular, the temperature and the duration of the at least part of the atomic layer deposition process 236 may be selected such that the amorphized regions 234, 235 re-crystallize substantially completely during the atomic layer deposition process 236. Thus, after the atomic layer deposition process 236, the material of the amorphized regions 234, 235 may have a crystalline structure, without there being a need for performing an additional annealing process.

The re-crystallization of the amorphized regions 234, 235 is a thermally activated process. In embodiments wherein the semiconductor region 204 includes silicon, a re-crystallization of the amorphized regions 234, 235 may occur when the semiconductor structure 200 is exposed to a temperature of about 500° C. or more. The time required for obtaining a substantially complete re-crystallization of the amorphized regions 234, 235 may depend on temperature, wherein, at a higher temperature, a faster re-crystallization of the amorphized regions 234, 235 may be obtained.

In some embodiments, at least a part of the atomic layer deposition process 236 may be performed at a temperature in a range from about 500-600° C. In some embodiments, at least a part of the atomic layer deposition process may be performed at a temperature in a range from about 550-600° C.

Performing the atomic layer deposition process 236 at a temperature of about 600° C. or less may help to reduce a diffusion of dopants, in particular a diffusion of dopants from the source extensions 223, 225, the drain extensions 224, 226 and the halo regions 227, 228, 229, 230. However, in some embodiments, temperatures of more than about 600° C. may be provided during at least a part of the atomic layer deposition process 236.

In some embodiments, the temperature at which the atomic layer deposition process is performed may be in a range from about 500-700° C., and the duration of the atomic layer deposition process may6 be in a range from about one hour to about seven hours.

When the amorphized regions 234, 235 re-crystallize during the atomic layer deposition process 236, the intrinsic stress of the layer 235 of material may create an intrinsic stress in crystalline semiconductor material that is formed when the amorphous semiconductor material in the amorphized regions 234, 235 re-crystallizes. Thus, during the atomic layer deposition process 236, stressed regions 245, 246 may be formed in the semiconductor region 204. The stressed regions 245, 246 may provide an intrinsic stress, in particular an intrinsic tensile stress, in the channel region of the transistor element 202 below the gate structure 207. The intrinsic tensile stress may improve the mobility of electrons, and, thus, may improve the performance of the N-channel transistor formed from transistor element 202.

Similar to the stressed regions 138, 139 formed in the stress memorization technique described above with reference to FIGS. 1a and 1b, the stressed regions 245, 246 formed in the semiconductor region 204 may maintain their intrinsic stress when parts of the layer 235 of material are removed in later stages of the manufacturing process for forming sidewall spacers from the layer 235 of material, as will be described below with reference to FIG. 2c.

In some embodiments, a substantially constant temperature of the semiconductor structure 200 may be provided during the entire atomic layer deposition process 236. In such embodiments, the duration of the atomic layer deposition process 236 may be in a range from about one hour to about seven hours.

The present disclosure, however, is not limited embodiments wherein the temperature at which the atomic layer deposition process 236 is performed is maintained substantially constant during the atomic layer deposition process.

In some embodiments, a first part of the atomic layer deposition process 236 may be performed at a relatively low temperature. The first part of the atomic layer deposition process 236 may be performed at a temperature of less than about 500° C., for example at a temperature in a range from about 400-500° C. and/or at a temperature in a range from about 400-450° C., wherein substantially no re-crystallization of material in the amorphized regions 234, 235 is obtained, or only a relatively small amount of re-crystallization occurs.

During the first part of the atomic layer deposition process 236, a number of atomic layer deposition cycles adapted for depositing a part of the layer 235 of material may be performed. The part of the layer 235 of material formed in the first part of the atomic layer deposition process may have an intrinsic stress, so that, at the end of the first part of the atomic layer deposition process 236, substantially the entire amorphized regions 234, 235, or at least a relatively large part of the amorphized regions 234, 235, is exposed to the stress provided by the first part of the layer 235 of material.

A second part of the atomic layer deposition process 236 may be performed at a relatively high temperature that is sufficient for obtaining a substantially complete re-crystallization of the amorphized regions 234, 235 during the second part of the atomic layer deposition process 236. The second part of the atomic layer deposition process 236 may be performed at a temperature greater than about 500° C. and/or at a temperature greater than about 550° C. In particular, the second part of the atomic layer deposition process may be performed at a temperature in a range from about 500-700° C., in a range from about 500-600° C. and/or in a range from about 550-600° C. In the second part of the atomic deposition process 236, a second part of the layer 235 of material may be formed, which may also have an intrinsic stress.

Compared to embodiments wherein the atomic layer deposition process is performed at a substantially constant temperature, increasing the temperature during the atomic layer deposition process 236 may help to provide a greater intrinsic stress in the stressed regions 245, 246 of the semiconductor region 204, since, in such embodiments, a greater portion of the layer 235 of material having an intrinsic stress may be present during the re-crystallization of substantial amounts of the material in the amorphized regions 234, 235.

In some embodiments, a substantially constant temperature may be provided during the first part of the atomic layer deposition process 236, and a substantially constant temperature may be provided during the second part of the atomic layer deposition process 236, wherein the temperature in the second part of the atomic layer deposition process 236 is greater than the temperature in the first part of the atomic layer deposition process. Alternatively, the temperature of the semiconductor structure 200 may be continuously increased during the atomic layer deposition process 236. For example, a linear increase of temperature may be provided during the atomic layer deposition process 236.

When the temperature of the semiconductor structure 200 is increased during the atomic layer deposition process 236, other parameters of the atomic layer deposition process 236, for example the pressure of the first and the second precursor, respectively, provided during the first and the second phase of each atomic layer deposition cycle, a duration of the atomic layer deposition cycles and/or durations of the phases of the atomic layer deposition cycles, may be varied in accordance with the increase of temperature, so that a self-limiting growth of material is obtained during the entire atomic layer deposition process 236. Thus, a highly conform layer 235 of material can be obtained.

FIG. 2c shows a schematic cross-sectional view of the semiconductor structure 200 in a later stage of the manufacturing process. After the atomic layer deposition process 236, an anisotropic etch process may be performed for forming a sidewall spacer 237 adjacent the gate structure 207 of the transistor element 202 and a sidewall spacer 238 adjacent the gate structure 208 of the transistor element 203 from the layer 235 of material. A duration of the anisotropic etch process may be adapted such that portions of the layer 235 of material on substantially horizontal portions of the surface of the semiconductor structure 200 are removed, wherein the liner layer 234 may be used as an etch stop layer. Portions of the layer 235 of material on the sidewalls of the gate structures 207, 208 may remain on the semiconductor structure 200 and form the sidewall spacers 237, 238.

Thereafter, ion implantation processes may be performed for forming a source region 247 and a drain region 248 in the transistor element 202, and for forming a source region 249 and a drain region 250 in the transistor element 203.

In embodiments wherein the transistor element 202 is an N-channel transistor element, an N-type dopant may be implanted into the semiconductor region 204 for forming the source region 247 and the drain region 248. In embodiments wherein the transistor element 203 is a P-channel transistor element, a P-type dopant may be implanted into the semiconductor region 205 for forming the source region 249 and the drain region 250. The semiconductor region 205 may be covered by a mask during the formation of the source region 247 and the drain region 248, and the semiconductor region 204 may be covered by a mask during the formation of the source region 249 and the drain region 250.

Ion doses implanted during the formation of the source regions 247, 249 and the drain regions 248, 250 may be sufficient for obtaining an N-type conductivity in portions of the semiconductor region 204 wherein the source and drain regions 247, 248 overlap with the halo regions 227, 228, and for obtaining a P-type conductivity in portions of the semiconductor region 205 where the source and drain regions 249, 250 and the halo regions 229, 230 overlap.

Thereafter, a cleaning process, which may be an etch process adapted for selectively removing the material of the liner layer 234 and the cap layers 212, 216, may be performed. In embodiments wherein the cap layers 212, 216 and the liner layer 234 include silicon dioxide, the cleaning process may include exposing the semiconductor structure 200 to diluted hydrofluoric acid. In the cleaning process, semiconductor material in the semiconductor regions 204, 205 and the gate electrodes 211, 215 is exposed.

Thereafter, a silicide portion 239 may be formed at the source side of the gate structure 207, a silicide portion 240 may be formed in the gate electrode 211 and a silicide portion 241 may be formed at the drain side of the gate structure 207. Similarly, silicide portions 242, 243, 244 may be formed at the source side of the gate structure 208, in the gate electrode 215 and at the drain side of the gate structure 208. This may be done by depositing a layer of a refractory metal, such as nickel, tungsten, cobalt and/or platinum, and performing an annealing process, for example a rapid thermal annealing process, for initiating a chemical reaction wherein silicide is created from the metal and the semiconductor material of the semiconductor structure 200. Thereafter, an etch process may be performed for removing metal that has not been consumed in the formation of the silicide.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
providing a semiconductor structure comprising a gate structure provided over a semiconductor region;
performing an ion implantation process that amorphizes a first portion of said semiconductor region adjacent said gate structure and a second portion of said semiconductor region adjacent said gate structure so that a first amorphized region and a second amorphized region are formed adjacent said gate structure; and
performing an atomic layer deposition process that deposits a layer of a material having an intrinsic stress over said semiconductor structure, a temperature at which at least a part of said atomic layer deposition process is performed and a duration of said at least a part of said atomic layer deposition process being selected such that said first amorphized region and said second amorphized region re-crystallize during said atomic layer deposition process.

2. The method of claim 1, wherein said first and said second amorphized regions re-crystallize substantially completely during said atomic layer deposition process.

3. The method of claim 2, wherein the re-crystallization of said first and said second amorphized regions forms a first and a second stressed region adjacent said gate structure, said first and said second stressed regions having an intrinsic stress.

4. The method of claim 3, wherein the intrinsic stress of said layer of said material deposited by said atomic layer deposition process is a tensile stress, and wherein the intrinsic stress of said first and said second stressed regions is a tensile stress.

5. The method of claim 1, wherein said at least a part of said atomic layer deposition process is performed at a temperature that is greater than at least one of 500° C. and 550° C.

6. The method of claim 5, wherein said at least a part of said atomic layer deposition process is performed at a temperature in at least one of a range from about 500-700° C., a range from about 500-600° C. and a range from about 550-600° C.

7. The method of claim 6, wherein the temperature at which said atomic layer deposition process is performed is maintained substantially constant during said atomic layer deposition process, and a duration of said atomic layer deposition process is in a range from about one hour to about seven hours.

8. The method of claim 1, wherein said layer of said material deposited by said atomic layer deposition process comprises silicon nitride.

9. The method of claim 8, wherein said atomic layer deposition process comprises alternately supplying a first precursor comprising silicon and a second precursor comprising nitrogen to a surface of said semiconductor structure, wherein said first precursor comprises at least one of monochlorosilane, dichlorosilane, trichlorosilane and tetrachlorosilane, and wherein said second precursor comprises at least one of ammonia and hydrazine.

10. The method of claim 1, wherein said ion implantation process comprises irradiating said semiconductor structure with ions of at least one of a noble gas and an element from the carbon group of the periodic table of elements.

11. The method of claim 10, wherein said ion implantation process additionally comprises irradiating said semiconductor structure with ions of at least one of fluorine and nitrogen.

12. The method of claim 1, wherein said gate structure comprises:
a gate electrode provided above said semiconductor region;
a gate insulation layer provided between said semiconductor region and said gate electrode; and
a first sidewall spacer formed at sidewalls of said gate electrode.

13. The method of claim 12, wherein said gate insulation layer comprises a high-k material having a dielectric constant greater than a dielectric constant of silicon dioxide, and said gate electrode comprises a metal.

14. The method of claim 12, further comprising:
before performing said atomic layer deposition process, forming an extended source region and an extended drain region adjacent said gate structure, the formation of said extended source region and said extended drain region comprising implanting ions of a dopant material; and
after performing said atomic layer deposition process, performing an anisotropic etch process, said anisotropic etch process forming a second sidewall spacer at sidewalls of the gate structure from said layer of said material deposited in said atomic layer deposition process and forming a source region and a drain region adjacent said gate structure, the formation of said source region and said drain region comprising implanting ions of a dopant material into said semiconductor region.

15. The method of claim 1, wherein the temperature at which said atomic layer deposition process is performed is increased during said atomic layer deposition process.

16. A method, comprising:
providing a semiconductor structure, said semiconductor structure comprising:
a first transistor element, said first transistor element comprising a first gate structure provided on a first semiconductor region; and
a second transistor element, said second transistor element comprising a second gate structure provided on a second semiconductor region;
the method further comprising:
forming a first amorphized region in said first semiconductor region adjacent said first gate structure and a second amorphized region in said first semiconductor region adjacent said first gate structure, wherein no amorphized region is formed in said second semiconductor region; and
performing an atomic layer deposition process that deposits a layer of a material having an intrinsic stress above said first semiconductor region and said second semiconductor region, a temperature at which at least a part of said atomic layer deposition process is performed and a duration of said at least a part of said atomic layer deposition process being selected such that said first amorphized region and said second amorphized region re-crystallize substantially completely during said atomic layer deposition process.

17. The method of claim 16, wherein the formation of said first amorphized region and said second amorphized region comprises performing an ion implantation process wherein ions of at least one of a noble gas and an element from the carbon group of the periodic table of elements are implanted into said first semiconductor region.

18. The method of claim 17, wherein said second semiconductor region comprises a stress-creating layer of silicon/germanium formed on silicon.

19. The method of claim 18, wherein:
said first gate structure comprises a first gate insulation layer comprising a high-k material having a dielectric constant that is greater than a dielectric constant of silicon dioxide, a first gate electrode comprising a first metal and a first sidewall spacer;
said second gate structure comprises a second gate insulation layer comprising a high k material having a dielectric constant that is greater than a dielectric constant of silicon dioxide, a second gate electrode comprising a second metal and a second sidewall spacer;
the method further comprises:
before performing said atomic layer deposition process, selectively implanting ions of an N-type dopant into said first semiconductor region to form a first source extension region and a first drain extension region adjacent said first gate structure and selectively implanting ions of a P-type dopant into said second semiconductor region to form a second source extension region and a second drain extension region adjacent said second gate structure; and
after performing said atomic layer deposition process, performing an anisotropic etch process to form from said layer of said material deposited in said atomic layer deposition process a third sidewall spacer at said first gate structure and a fourth sidewall spacer at said second gate structure, selectively implanting ions of an N-type dopant into said first semiconductor region to form a first source region and a first drain region adjacent said first gate structure and selectively implanting ions of a P-type dopant into said second semiconductor region to form a second source region and a second drain region adjacent said second gate structure.

20. The method of claim 19, wherein the formation of said first amorphized region and said second amorphized region additionally comprises implanting ions of at least one of fluorine and nitrogen into said first semiconductor region.

21. The method of claim 20, wherein the temperature at which said atomic layer deposition process is performed is increased during said atomic layer deposition process.
